(19) United States
(12) Patent Application Publication
(10) Pub. No.: US 2014/0050865 A1
(43) Pub. Date: Feb. 20, 2014

(54) APPARATUS AND METHOD FOR COATING USING A HOT WIRE

(71) Applicants: Stefan Bangert, Steinau (DE); Werner Guhr, Freigericht (DE); Stefan Keller, Mainaschaff (DE); Michael König, Malsch (DE)

(72) Inventors: Stefan Bangert, Steinau (DE); Werner Guhr, Freigericht (DE); Stefan Keller, Mainaschaff (DE); Michael König, Malsch (DE)

(73) Assignee: APPLIED MATERIALS, INC., Santa Clara, CA (US)

(21) Appl. No.: 14/005,115

(22) PCT Filed: Mar. 22, 2011
(86) PCT No.: PCT/EP2011/054365

§ 371 Date: Nov. 11, 2013

(51) Int. Cl. C23C 16/448

(52) U.S. Cl. CPC C23C 16/448
USPC 427/587; 118/726

(57) ABSTRACT

A coating apparatus (700) is provided including: (i) a vacuum chamber (16) for coating a substrate (12) with coating material heated by a wire (14); and (ii) an actuator system (18) including a motorised drive (20). The actuator system is configured for tensioning the wire (14) during the coating. Furthermore, a method of manufacturing a coated substrate (12) is provided including: (i) tensioning a wire (14) by an actuator system (18) including a motorised drive; and (ii) coating the substrate (12) with a coating material (28), the coating being under vacuum conditions. The coating includes heating at least a portion (14a) of the wire (14) to an operating temperature for inducing a temperature increase in the coating material before the coating material is deposited over substrate (12).

### TECHNICAL FIELD

Embodiments of the present invention relate to apparatuses and methods for coating a substrate. In particular, embodiments of the present invention relate to coating apparatuses and methods for implementing a wire or wires as hot element of the system. Specifically, embodiments herein relate to a coating apparatus and a method of manufacturing a coated substrate.

### BACKGROUND ART

A coating apparatus may implement a heating wire (or wires) as a hot element for performing coating of a substrate. In particular, the heating wire (or wires) may be heated to a sufficiently high temperature. Generally, material in the gas phase interacts with a heated wire (e.g. by flowing over, or coming into physical contact with the wire) before being deposited over the substrate. Generally, the interaction of material to be deposited with the wire induces a physical and/or chemical transformation on the deposition material. Such a material is generally referred to as a deposition precursor. For example, the heated wire may induce a temperature increase of the deposition material such that the deposition material is decomposed through a chemical reaction. For example, such a coating apparatus may constitute a hot wire chemical vapour deposition (HWCVD) system.

Generally, the operating life of a wire being used as hot element in a coating apparatus is limited. Therefore, the wire (or wires) may require to be replaced after a certain operational time. This operational time may be relatively short, for example, between one to seven days of operation. This may imply relatively extensive downtimes and relatively frequent servicing of the coating apparatus. Extensive downtimes and frequent servicing generally imply an increase of manufacturing costs and reduction of productivity of the coating apparatus.

Therefore, there is a need for apparatuses and methods that facilitate increasing the operating life of a wire (or wires) constituting the hot element of a coating apparatus.

### SUMMARY OF THE INVENTION

In light of the above, coating apparatuses according to independent claims 1 and 3, and a method of manufacturing a coated substrate according to independent claim 11 are provided. Further aspects, advantages and features of the present invention are apparent from the dependent claims, the description and the accompanying drawings.

In one embodiment, a coating apparatus is provided. The coating apparatus includes: a vacuum chamber for coating a substrate; a reactor adapted to receive at least a wire portion for heating material to be deposited on said substrate; a motorised drive, including at least one electrical motor; and a wire roller system configured for feeding and positioning at least the wire portion in said reactor. The motorised drive is operatively coupled to the wire roller system, so that, in use, at least the wire portion positioned in the reactor can be tensioned in an adjustable manner by the motorised drive.

In another embodiment, a coating apparatus is provided including: a vacuum chamber for coating a substrate with coating material heated by a wire; and an actuator system including a motorised drive, the actuator system being configured for tensioning the wire during the coating.

In yet another embodiment, a method of manufacturing a coated substrate is provided. The method includes: tensioning a wire by an actuator system including a motorised drive; coating the substrate with a coating material, the coating being under vacuum conditions. The coating includes heating at least a portion of the wire to an operating temperature for inducing a temperature increase in the coating material before the coating material is deposited over substrate.

### BRIEF DESCRIPTION OF THE DRAWINGS

A full and enabling disclosure, including the best mode thereof, to one of ordinary skill in the art is set forth more particularly in the remainder of the specification, including reference to the accompanying figures wherein:

FIG. 1 is a schematic cross-section of an exemplary coating apparatus;

FIG. 2 is an exemplary method of manufacturing a coated substrate by, for example, operating the coating apparatus of FIG. 1;

FIG. 3 is a schematic cross-section of another exemplary coating apparatus;

FIG. 4 is an exemplary method of manufacturing a coated substrate by, for example, operating the coating apparatus of FIG. 3;

FIG. 5 is a schematic cross-section of the coating apparatus of FIG. 3 in a particular configuration;

FIG. 6 is a schematic cross-section of the coating apparatus of FIG. 3 in another particular configuration;

FIG. 7 is a schematic cross-section of yet another exemplary coating apparatus;

FIG. 8 is a schematic cross-section of another exemplary coating apparatus;

FIG. 9 is a schematic cross-section of yet another exemplary coating apparatus;

FIG. 10 is a schematic diagram of a control system adapted for operating a coating apparatus according to embodiments herein.

### DETAILED DESCRIPTION OF THE INVENTION

Reference will now be made in detail to the various embodiments, one or more examples of which are illustrated in each figure. Each example is provided by way of explanation and is not meant as a limitation. For example, features illustrated or described as part of one embodiment can be used on or in conjunction with other embodiments to yield yet further embodiments. It is intended that the present disclosure includes such modifications and variations.

The embodiments described herein include a coating apparatus including a vacuum chamber for coating a substrate with coating material heated by a wire. In particular, according to typical embodiments, the substrate is coated with a coating material being a dissociated precursor. Typically, the precursor is dissociated by the wire heating. In particular, the coating apparatus may be configured to: (i) receive a wire (for example, in a reactor of the apparatus); (ii) heat the wire (or at least a portion thereof in a reactor); and (iii) heating a coating material interacting with the heated wire, so that the coating material chemically reacts and dissociates. Further, the coating apparatus may include an actuator system with a motorised drive. The actuator system is configured for tensioning the wire during the coating. Such an actuator system including a motorised drive facilitates a proper tensioning of the wire. More specifically, a coating apparatus according to embodiments herein facilitates adjusting tensioning of the wire during a coating process.

Embodiments herein generally facilitate avoiding generation of excessive stress on the wire through the tensioning system. Such an excessive stress might decrease the operating life of the wire. Furthermore, an actuator system including a motorised drive according to embodiments herein generally facilitates a simplified tensioning mechanism. For example, at least some of the embodiments herein do not implement a spring tensioning system coupled to the wire for tensioning thereof. According to yet further embodiments, which can be combined with other embodiments, described herein, the actuators system can also be utilized for feeding the wire or an additional portion of the wire in the region in which the wire is heated.

A vacuum chamber according to embodiments herein may be any chamber with at least a portion thereof adapted for sustaining vacuum conditions, namely a pressure below 10 mbar or, more specifically, a pressure below 10⁻³ mbar. In particular for embodiments directed to chemical vapour deposition (CVD), the vacuum chamber is configured to be operated at a pressure between 1 mbar and 10⁻² mbar. The terms “coating” and the term “depositing” are used synonymously herein. Typically, “coating” refers to a process for applying a thin film of a coating material on a substrate.

According to typical embodiments, coating includes, or consists of, CVD of a coating material. Alternatively, coating may include, or consist of, physical vapour deposition (PVD) of a coating material. Coating may include a combination of CVD and PVD of a coating material. According to typical embodiments, a coating material is a material to be deposited on a substrate or a material deposited over the substrate. A coating material may include multiple components, which may be simultaneously and/or sequentially deposited on a substrate.

According to typical embodiments, a wire is an elongated piece or filament (generally slender and/or string-like) including material suitable for heating a coating material. For example, but not limited thereto, the wire may be a flexible filament including a resistive material that may be heated to a suitable operating temperature by the passage of current. For example, but not limited thereto, the wire may be a Ta or W wire. A wire according to embodiments herein may constitute the hot wire in an apparatus for HWCVD.

According to typical embodiments, an actuator system is a mechanism configured to effect tensioning and/or translation of at least a portion of the wire. For example, the actuator system may supply and transmit mechanical energy to the wire in order to tension the wire or for translate the wire within the region in which the wire is heated. According to typical embodiments, a motorised drive is a drive including at least one motor, which drive is configured to generate one or more forces for tensioning of a wire through one or more elements adapted to be coupled to the wire. For example, such a force might be generated through elements of the actuator system for tensioning, adjusting tension, and/or translating at least a portion of a wire. The actuator element may include one or more rotatable elements, which may be operated through the generation of momentums or torques through a motorised drive for effecting tensioning of the wire. In addition thereto, such momentums or torques might be generated for introducing a new wire portion in a reaction area or reactor of a coating apparatus.

Within the following description of the drawings, the same reference numbers refer to the same components. Generally, only the differences with respect to the individual embodiments are described.

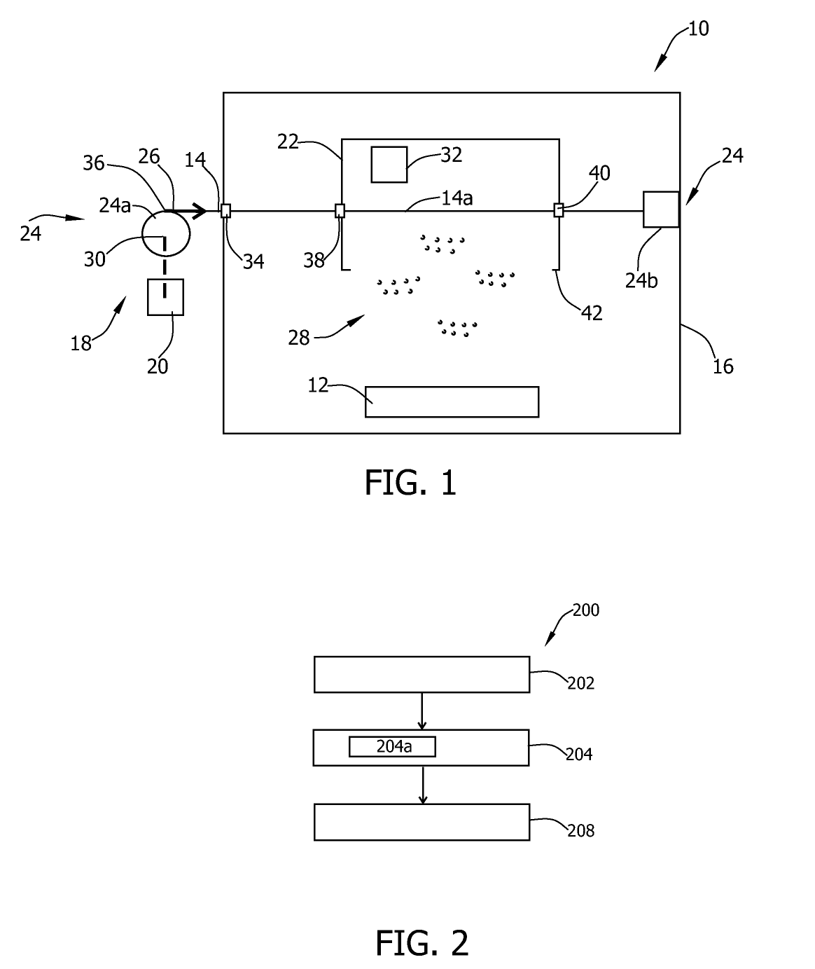

FIG. 1 is a schematic cross-section of an exemplary coating apparatus 10. Exemplary coating apparatus 10 includes a vacuum chamber 16 configured to receive a substrate 12 on a substrate support (not shown). Coating apparatus 10 is further configured for receiving a wire 14. In the exemplary embodiment, coating apparatus 10 includes a reactor 22 configured to receive a portion 14a of wire 14. According to embodiments herein, reactor 22 is a particular portion of a coating apparatus configured to allow interaction of a coating material 28 with wire 14 for heating of coating material 28. According to further embodiments, which can be combined with other embodiments described herein, the portion 14a of the wire can also be provided in a reaction region within the chamber 16.

According to embodiments herein, coating apparatus 10 is configured such that wire 14 interacts with a coating material 28 (e.g. for heating thereof) before deposition of coating material 28 over substrate 12. In particular, reactor 22 may be constituted by a chamber configured to receive: (i) coating material 28 in vaporized, gaseous, or volatized form (ii) a wire portion 14a for heating of coating material 28 in vaporized, gaseous, or volatized form. According to some embodiments, coating material 28 may be a precursor gas suitable for performing CVD over substrate 12.

A coating apparatus according to embodiments herein may include means for introducing coating material 28 into reactor 22 such as, but not limited to, inlets and/or vents disposed in reactor 22. According to other embodiments, coating material 28 may be provided onto wire 14 such that coating material 28 on wire 14 can be heated by heating wire 14. According to embodiments herein, coating material 28 is heated by wire 14 for effecting decomposition of coating material 28, as further detailed below.

Reactor 22 may further include an outlet 42 for allowing coating material 28 that has been heated by wire 14 to deposit over substrate 12. In such embodiments, reactor 22 may be provided with feedthroughs 38, 40, so that a wire portion 14a may be positioned within reactor 22 according to embodiments herein. In particular, feedthroughs 38, 40 may be configured for allowing wire portion 14a (or any other portion of wire 14) to be fed into reactor 22 and exit therefrom.

According to typical embodiments, coating apparatus 10 includes heating system 32 for heating at least wire portion 14a, disposed within reactor 22. Additionally or alternatively, other portions of wire 14 could be heated by heating system 32. Thereby, a wire portion positioned in reactor 22 (such as wire portion 14a) can induce a temperature increase of coating material 28 before coating material 28 deposits over substrate 12. In some embodiments, which are further detailed below, wire 14 includes a resistive material, and heating system 32 includes an electrode system for applying an electrical current through at least a portion wire 14 for heating of that wire portion.

Alternatively, heating system 32 may include any heating source suitable for and, typically, configured to heat at least a portion wire 14, so that coating material 28 can be heated in reactor 22 before deposition thereof over substrate 12. In at least some embodiments herein, heating system 32 is provided within vacuum chamber 16 or, more specifically, within reactor 22. Alternatively, heating system 32 may be configured for being coupled to wire 14 outside reactor 22 and/or vacuum chamber 16.

According to typical embodiments, coating apparatus 10 includes a wire tensioning system for tensioning at least a portion of wire 14. In particular, coating apparatus 10 includes an actuator system 18 including a motorised drive 20. According to embodiments herein, motorised drive 20 includes at least one electrical motor selected from the group consisting of servomotors and stepper motors. In particular, motorised drive 20 may include an electrical motor such as, but not limited to, a servo motor. Alternatively or in combination thereto, motorised drive 20 may include a stepper motor. Actuator system 18 is configured to tension at least a portion of wire 14 such as, but not limited to, wire portion 14a, during the coating of substrate 12.

According to typical embodiments, actuator system 18 is configured for tensioning wire 14 by generating a linear force (i.e., a force generated by linear motion of a motorized drive) and/or one or more momentums or torques through motorised drive 20. In the exemplary embodiment, actuator system 18 includes a tensioning system 24 including a pull device 24a and a fixing means 24b. Pull device 24a and fixing means 24b are typically configured to: (i) positioning wire portion 14a within reactor 22, and (ii) tensioning at least wire portion 14a.

Fixing means 24b may be any suitable device for fixing a portion of wire 14 such that wire portion 14a can be tensioned within reactor 22. For example, but not limited to, fixing means 24b may be a clamp at a wall of vacuum chamber 16. Alternatively fixing means 24b may be an additional pull device similar to pull device 24a but placed at an opposite side of reactor 22, so that a wire portion extends between both pull devices and within an area for heating coating material 28 before deposition thereof, such as reactor 22. Alternatively, fixing means 24b may be a wire roller configured to: (i) store a portion of wire 14, and (ii) collaborate in the tensioning of the wire portion in reactor 22, as further detailed below.

In the exemplary embodiment, and other embodiments herein, pull device 24a may be configured to pull wire 14 at a position 36 such that wire 14 is tensioned. Pull device 24a may include or be operatively coupled to motorised drive 20 for effecting tensioning of wire 14. Pull device 24a may be any device suitable for applying a tension 26 on wire 14, so that wire 14 may be actuated as described herein. For example, pull device 24a may be an actuator configured for tensioning wire 14 through the generation of a momentum or torque. Alternatively or in combination thereto, pull device 24a may configured to couple a linear force to wire 14, for tensioning thereof.

In particular, pull device 24a may be a torque device having a rotating wheel operated by motorised drive 20. An end portion of wire 14 may be attached to the rotating wheel at a position 36. Such a rotating wheel may be capable of generating a torque with respect to the wheel rotational axis 30 at position 36, where wire 14 is coupled to the wheel. According to other embodiments, pull device 24a may be a wire roller configured for: (i) storing a batch of wire 14, (ii) feeding wire 14 into reactor 22, and (iii) collaborating in the tensioning of wire 14 during coating, as further discussed below. In other embodiments, pull device 24a is a solid beam or a flexure movable by motorised drive 20 for generating a torque such that a portion of wire 14 is tensioned. Such a solid beam or flexure may be capable of generating a torque at the point where wire 14 is coupled to the solid beam or flexure. Such a torque may be generated relative to a stationary or hinged portion of the solid beam or flexure.

According to some embodiments, actuator system 18 is configured to tension wire 14 by applying any suitable force thereon. For example, actuator system 18 may be configured for coupling a force generated by linear motion of element in a motor. In particular, such a linear force may be generated by an actuating element translatable parallel to a predetermined translational axis. The linear actuating element may be, for example, but not limited to, a hydraulic actuator.

According to some embodiments, which may be combined with any other embodiment herein, motorised drive 20, in particular a motor, or motors thereof, is operated by using a torque control system. Thereby, wire 14 (or at least a portion thereof) may be maintained in a straight position with high control accuracy. In particular, thereby, wire 14 may be appropriately positioned in reactor 22 at a predetermined tension and without generating excessive stresses on wire 14. Motorised drive 20 may be operated automatically, for example, by a motor control system as further detailed below. Alternatively, motorised drive 20 may be manually controlled. For example, motorised drive 20 may be operated through a switch, motion control interface, or a torque control interface for tensioning wire 14 to an appropriate tension suitable for allowing coating apparatus 10 to function as described herein.

In the exemplary embodiment, reactor 22 is included in vacuum chamber 16. According to alternative embodiments, reactor 22 is disposed outside vacuum chamber 16 but in communication therewith, so that coating material 28 can be introduced in vacuum chamber 16 after interacting with wire 14.

According to some embodiments, actuator system 18 may be provided outside of vacuum chamber 16. According to other embodiments, actuator system 18 may be provided within vacuum chamber 16. According to other embodiments, a first group of elements of actuator system 18 may be provided within vacuum chamber 18 and a second group of elements of actuator system 18 may be provided outside of vacuum chamber 16. For example, in the embodiment of FIG. 1 and other embodiments herein, actuator system 18 is partially disposed outside vacuum chamber 16. In particular, motorised drive 20 and pull device 24a may be provided outside vacuum chamber 16, while fixing means 24b may be provided within vacuum chamber 16.

In the exemplary embodiment, wire 14 is fed to vacuum chamber 16 through a feedthrough 34. Typically, feedthrough 34 is configured to allow feeding of wire 14 into vacuum chamber 16, while vacuum chamber 16 is being kept at vacuum conditions. In other embodiments, for example when actuator system is provided within vacuum chamber 16, vacuum chamber 16 may not require a feedthrough system (such as feedthrough 34) for allowing positioning of wire 14 within vacuum chamber 16.

FIG. 2 shows an exemplary method 200 of manufacturing a coated substrate 12 by, for example, operating exemplary coating apparatus 10 of FIG. 1 or any other coating apparatus according to embodiments herein. Exemplary method 200 includes tensioning 202 wire 14 by actuator system 18, which actuator system 18 includes motorised drive 20. Method 200 further includes coating 204 substrate 12 with coating material 28 under vacuum conditions. Coating 204 includes heating 204a wire 14. For example, coating 204 may include heating at least a portion of wire 14 such as, but not limited to, wire portion 14a, to an operating temperature. Typically, the operation temperature is a temperature suitable for inducing a temperature increase in coating material 28, so that coating material 28 may be deposited over substrate 12 under a predetermined condition. In particular, the operation temperature may be such that coating material 28 in reactor 22 can undergo a chemical process e.g., reaction and/or decomposition on the surface of substrate 12 to produce a desired deposit.

According to typical embodiments, coating apparatus 10 is configured for heating wire 14 while wire 14 is tensioned by actuator system 18. Method 200 may further include such heating of tensioned wire 14. Alternatively, or in combination thereto, coating apparatus 10 may be configured for heating wire 14 in a non-tensioned form. Method 200 may further include such heating of non-tensioned wire 14.

Tensioning 202 may, optionally, further include coupling a force or, more specifically, a torque, generated by the motorised drive to the wire through a non-resilient coupling system. For example, coating system 10 may be configured for tensioning wire 14 by an actuator system not including a spring tensioning system directly coupled to wire 14 for tensioning thereof. Method 200 may, optionally, further include adjusting 208 tension of at least wire portion 14a by controlling a generated torque during a coating process.

According to some embodiments, actuator system 18 further includes a wire feeding device operated by the motorised drive for providing a new portion of wire. Thereby, a wire portion in a reaction area may be replaced by a new wire portion, so that a coating material can be heated with a new wire portion before deposition of that material. According to embodiments herein, the term “new wire portion” refers to a wire portion different, at least partially, from another wire portion, which has been used for increasing temperature of a coating material or has been placed in an area adapted thereto (such as wire portion 14a).

In particular, actuator system 18 may be configured for: (i) tensioning wire 14 during coating; and (ii) feeding a new wire portion into reactor 22 or other reaction area of the system. Thereby, at least some embodiments herein provide an actuator system, which does not only facilitate a proper tensioning of wire 14 but also facilitates exchanging the wire portion configured for heating coating material. Such an actuator system not only facilitates reducing the downtime of a coating apparatus but, by providing tensioning and wire replacement, facilitates a simplified design of a coating apparatus according to embodiments herein.

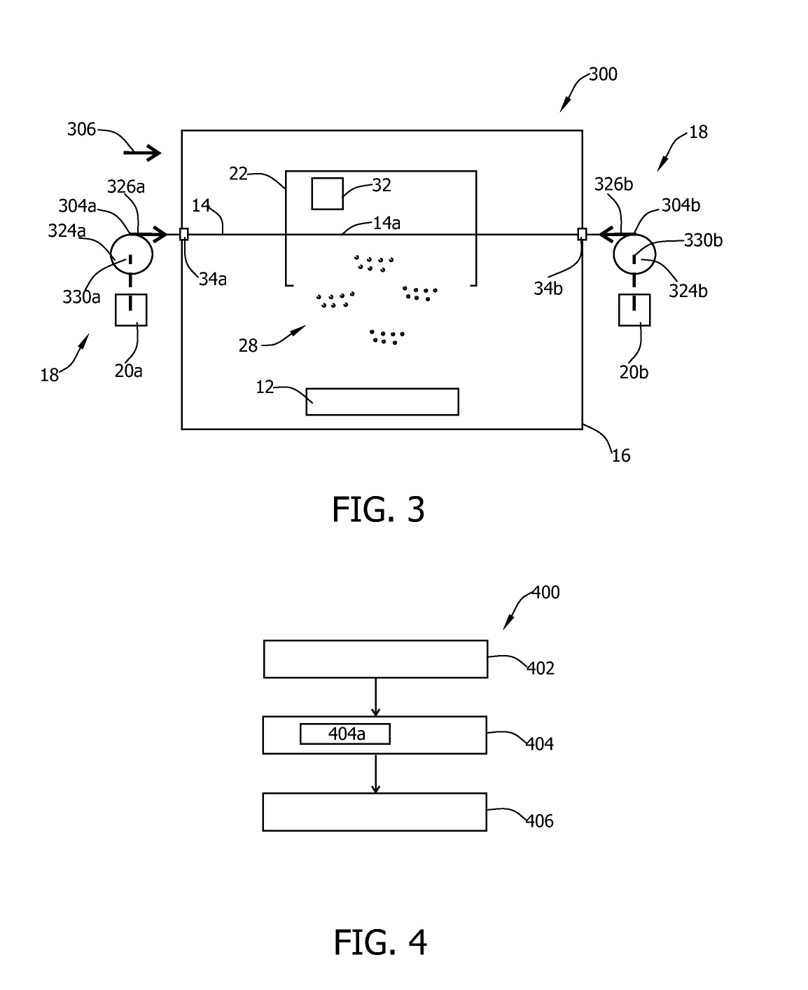

FIG. 3 is a schematic cross-section of an exemplary coating apparatus 300 including a wire feeding device. In this exemplary embodiment, the wire feeding device is constituted by a wire roller system. The wire roller system in the exemplary embodiment is configured for feeding wire in reactor 22. Furthermore, the wire portion in reactor 22 is typically positioned therein by the wire roller system. The wire roller system may include a wire roller 324a and a wire roller 324b, both wire rollers 324a, 324b forming part of actuator system 18.

The wire roller system may be configured for suspending wire 14 between wire rollers 324a, 324b, so that a wire portion (such as, wire portion 14a) is positioned in reactor 22. In particular, both wire rollers 324a, 324b may constitute a tensioning mechanism 24 according to embodiments herein. Each of wire rollers 324a, 324b may be configured for storing a portion of wire 14 (e.g., a batch of wire 14) such that another portion of wire 14 extends between both rollers. Typically, the wire portion extending between wire rollers 324a, 324b includes a wire portion disposed for heating of coating material 28.

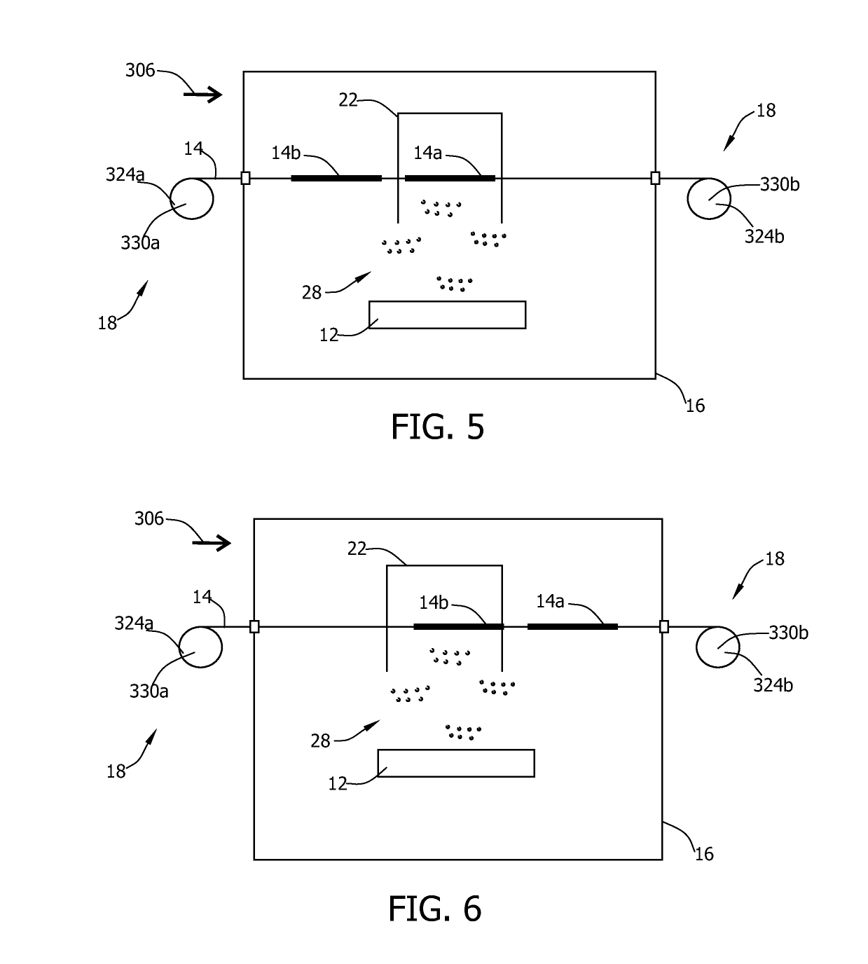

One of wire rollers 324a, 324b may be configured as an unwound roller for unwinding a portion of wire in collaboration with motorised drive 20 when required. For example, wire roller 324a may be operatively coupled to motorised sub-drive 20a for unwinding wire 14. Another of wire rollers 324a, 324b may be configured as an unwound roller for unwinding a portion of wire 14a in collaboration with motorised drive 20 when required. For example, wire roller 324b may be operatively coupled to motorised sub-drive 20b for winding wire 14. Thereby, as shown in FIGS. 5 and 6, coating apparatus 300 may be operable for introducing a new wire portion 14b into reactor 22. In this manner, the portion of wire 14 extending between both rollers may be varied. In particular, thereby, a new portion of wire may be fed for interacting with coating material 28. In exemplary coating apparatus 300, the wire feeding device is configured to feed a new wire portion in the direction of arrow 306.

According to one embodiment, both wire rollers 324a, 324b may be configured to be operated indistinctly as unwound roller or wound roller depending of the particular circumstances. According to particular embodiments, wire rollers 324a, 324b may be configured to be operated alternatively as unwound roller and wound roller.

According to some embodiments, wire feeding device may include additional rollers as wire rollers 324a, 324b. For example, actuator system 18 may include a set of guide rollers (not shown) or any other kind of roller system appropriate for allowing coating apparatus 300 to function as disclosed herein. For example, wire portion 14a may extend between two guide rollers, each of the two guide rollers being disposed adjacently to a respective wire roller 324a, 324b.

According to typical embodiments, a wire feeding device is operatively coupled to a motorised drive system for performing wire feeding and wire tensioning. In coating apparatus 300 wire rollers 324a, 324b respectively collaborate with motorised sub-drives 20a, 20b for: (i) feeding a new portion of wire for interacting with coating material 28, as set forth above; and (ii) tensioning wire 14 during coating. In particular, motorised sub-drives 20a, 20b may be configured to operate wire rollers 324a, 324b for: (i) feeding a new portion of wire into reactor 22 when required; and (ii) maintaining a proper tension of the wire portion extending between both rollers. In particular, actuator system 18 may be configured for maintaining a substantially constant wire tension during wire feeding. Motorised sub-drives 20a, 20b may be operated in a synchronous manner for example, by a motor control system, as further discussed below.

In exemplary coating apparatus 300, wire rollers 324a, 324b are, respectively, operatively coupled to motorised sub-drives 20a, 20b for generating torques 326a, 326b, which torques cause tensioning of wire 14 as described herein. Torques 326a, 326b are considered relative to rotational axis 330a, 330b of wire rollers 324a, 324b. In particular, torques 326a, 326b may be generated at the points of entry/exit 304a, 304b of wire 14 into/out wire rollers 324a, 324b. Torques 326a, 326b typically facilitate that wire 14, or at least a portion thereof positioned for interacting with coating material 28, can be tensioned in an appropriate manner. Furthermore, generation of torques 326a, 326b for tensioning of wire 14 is typically advantageous for adjusting the tension of wire 14, since torques may offer an appropriate means for controlling tensioning of wire 14.

In some embodiments, as depicted in FIG. 3, wire rollers 324a, 324b are disposed outside of vacuum chamber 16. In such embodiments, coating apparatus 300 may be further configured to: a) fed wire 14 into vacuum chamber 16 through a feedthrough (e.g. one of feedthrough 34a or 34b); and b) fed wire 14 out of vacuum chamber 16 through another feedthrough (e.g. one of feedthroughs 34a or 34b).

A coating apparatus according to embodiments herein may further include a wire treatment unit adapted for treating a wire portion before feeding thereof into reactor 22. This treated wire portion may be an unused wire portion. Alternatively, this treated wire portion may be a wire portion that has been previously used for heating coating material 28. For example, such a treatment unit may be coupled to an element of a wire feeding device of a coating apparatus according to the present disclosure. For example, such a treatment device may be coupled to at least one of wire rollers 324a, 324b. In particular, wire rollers 324a, 324b may be associated to a treatment system (not shown) for treating a used portion of wire 14, so that this portion may be re-utilized for heating of coating material.

FIG. 4 shows an exemplary method 400 of manufacturing a coated substrate 12 by, for example, operating exemplary coating apparatus 300 of FIG. 3 or any other coating apparatus including a wire feeding device according to embodiments herein. Exemplary method 400 includes tensioning 402 and coating 404 steps analogous to tensioning 202 and coating 204 steps described above. Coating 404 may include heating 404a coating material 28 by interaction thereof with wire portion 14a. According to at least some embodiments herein, method 400 further includes operating 406 actuator system 18 for supplying (i.e., feeding) a new portion 14b of wire 14 (see FIGS. 5 and 6) such that new wire portion 14b can be used for heating coating material 28, before deposition thereof over substrate 12.

According to at least some embodiments, in method 400 new wire portion 14b is supplied while coating material 28 is being deposited over substrate 12. That is, wire 14 may be fed continuously or discontinuously during coating, so that the wire portion interacting with coating material 28 is continuously or discontinuously replaced. By discontinuously feeding of wire 14, wire 14 is fed within, for example, reactor 22 during predetermined feed time periods followed by predetermined stop periods, in which wire 14 remains stationary. Wire 14 may be fed at a feed rate or an average feed rate between 0.1 mm/s and 1000 mm/s, such as 10 mm/s.

According to some embodiments, which might be combined with other embodiments herein, new wire portion 14b is supplied (i.e. fed) at predetermined time intervals. That is, wire 14 may remain stationary during a whole coating process (or at least a portion of a coating process). A new wire portion may be fed after a predetermined period of time of wire use has lapsed. For example, a new portion of wire may be fed (for example, into reactor 22) after a time of at least 10 hours of wire use has lapsed or, more specifically, after at least 8 hours or, even more specifically, after at least 6 hours. According to embodiments herein, time of wire use refers to the time that a particular portion of wire 14 (such as wire portion 14a) has been used for heating coating material 28.

A coating apparatus according to embodiments herein may include a heater configured to heat at least a wire portion (such as wire portion 14a in the figures). In particular, such a heater may be configured to heat the wire, or at least a portion thereof, to a temperature of at least 1500° C. or, more specifically, to at least 2800° C. In particular, the wire portion may be heated at a temperature between 1500° C. and 2800° C.

In at least some embodiments, the coating apparatus may be configured for receiving a resistive wire. In such embodiments, the coating apparatus may include an electrode system configured for applying an electrical current such that a wire portion is heated, so that a temperature increase may be induced on coating material to be deposited (e.g. coating material 28). A coating apparatus according to at least some embodiments herein may implement contact electrodes for resistive heating of wire 14, which contact electrodes are movable such that a proper tensioning and/or feeding of wire 14 by actuator system 18 is not compromised by the contact electrodes.

In particular, such an electrode system may include clamping electrodes configured to: (i) apply a current to the wire; and (ii) facilitate tensioning of the wire by an actuator system according to embodiments herein. Furthermore, such clamping electrodes may be further configured to (iii) facilitate the actuator system to feed a new wire portion according to embodiments herein.

Such clamping electrodes may be constituted by a non-active drive which is adapted to contact the wire without constraining movement of the wire in at least one direction (e.g., the wire tensioning direction, or the wire feed direction such as the direction of arrow 306). For example, such clamping electrodes may be constituted by planar electrodes, brush electrodes, rotatable roller electrodes configured to freely roll, or any other type of electrodes suitable and configured to contact the wire and allowing tensioning and translation thereof by the actuator system.

Alternatively or in combination thereto, the clamping electrodes may have movable elements (such as clamping rollers) operatively coupled to motorised drive 20 of an actuator system according to embodiments herein in order to allow: (i) proper tensioning of the wire by movement (e.g. rolling) of the clamping electrodes coordinated with the actuator system; and/or (ii) feeding of a new portion of wire by movement (e.g. rolling) of the clamping electrodes coordinated with a wire feeding device of the actuator system (such as, wire rollers 324a, 324b).

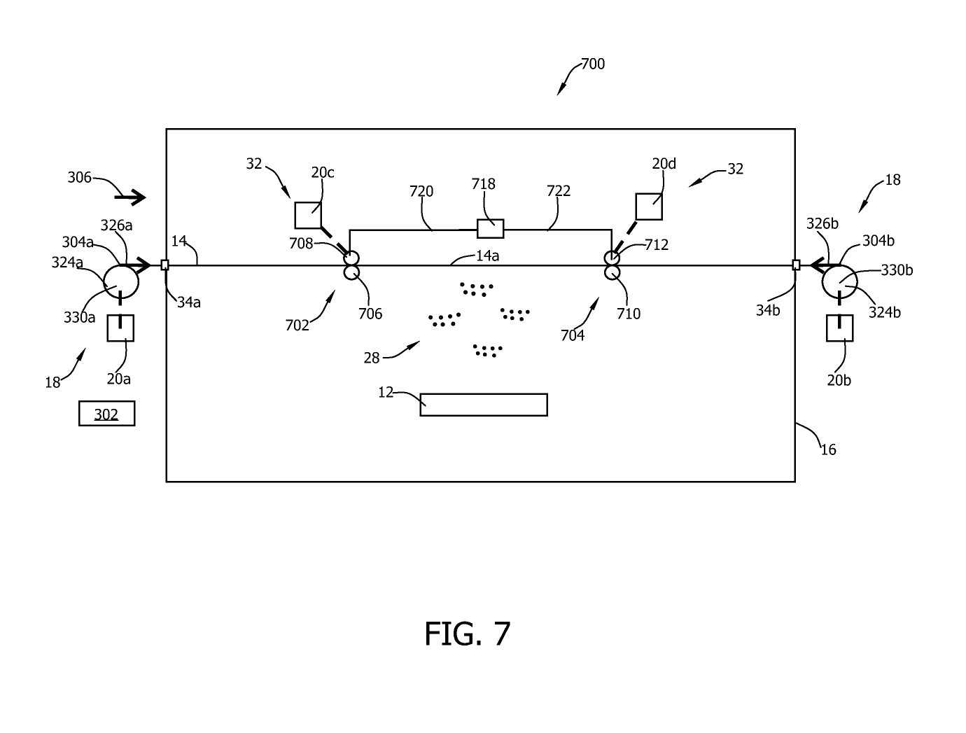

FIG. 7 shows a schematic cross-section of an exemplary coating apparatus 700. Exemplary coating apparatus 700 includes a first electrode coupling 702 and a second electrode coupling 704. Electrode couplings 702, 704 (and elements thereof) may be implemented in any other of the embodiments herein, such as those depicted in FIGS. 1 to 6 and 8 to 10. First and second electrode couplings 702, 704 may be configured to apply an electrical current in at least a portion of wire 14. Typically, this portion of wire 14 is a wire portion 14a configured for interacting with a coating material 28. Thereby, wire portion 14a may be heated to an operational temperature by an electrical current applied through electrode couplings 702, 704. First electrode coupling 702 and/or second electrode coupling 704 may include at least one roller operatively coupled to a motorised drive for actuation thereof. Thereby, wire portion 14a may be properly tensioned, fed and/or replaced by another wire portion through operation of actuator system 18 while electrode couplings 702, 704 are in contact with wire 14.

First electrode coupling 702 may include at least one couple of clamping rollers 706, 708 configured to cooperatively clamp wire 14. Thereby, first electrode coupling 702 may allow to: (i) apply a predetermined voltage on wire 14; and/or (ii) actuation of wire 14 by actuator system 18. Second electrode coupling 404 may also include at least one couple of clamping rollers 710, 712 configured to cooperatively clamp wire 14. Thereby, second electrode coupling 704 may allow to: (i) apply another predetermined voltage on wire 14; and/or (ii) actuation on wire 14 by actuator system 18.

The predetermined voltages may be such that a predetermined current can be applied onto wire 14, more particularly onto the portion of wire 14 clamped between electrode couplings 702, 704 (for example, but not limited to, wire portion 14a). In particular, electrode couplings 702, 704 may be electrically connected to a voltage source 718 through electrical connections 720, 722.

According to some embodiment, electrode couplings 702, 704 are respectively coupled to motorised sub-drives 20c, 20d for actuation thereof. According to other embodiments, electrode couplings 702, 704 are actuated, simultaneously, by a single motorised drive. According to embodiments herein, the motorised drive system operatively coupled to electrode couplings 702, 704 is operated by a motor control system, as further discussed below.

According to one embodiment, which may be combined with other embodiments herein, heating system 32 may be implemented in elements of actuator system 18. For example, elements of actuator system 18 adapted for being in contact with wire 14 may be further adapted for being used as an electrode coupling as described herein. In particular, elements of actuator system 18 adapted for being in contact with wire 14 may be electrically connected to voltage source 718 for applying an electrical current to at least a portion of wire 14. Such elements may be, for example, but not limited to, wire rollers 324a, 324b. Alternatively, additional electrode elements (such as brush electrodes) may be provided close to wire rollers 324a, 324b for applying a voltage to a wire portion close to entry points 304a, 304b of wire 14 into wire rollers 324a, 324b.

In the exemplary embodiment depicted in FIG. 7, electrode couplings 702, 704 are disposed within vacuum chamber 16. According to alternative embodiments, at least one of first electrode coupling 702 or second electrode coupling 704 may be disposed outside vacuum chamber 16. For example, electrode couplings 702, 704 may be disposed within vacuum chamber 16. Similarly, electrode couplings 702, 704 may be implemented within or outside reactor 22.

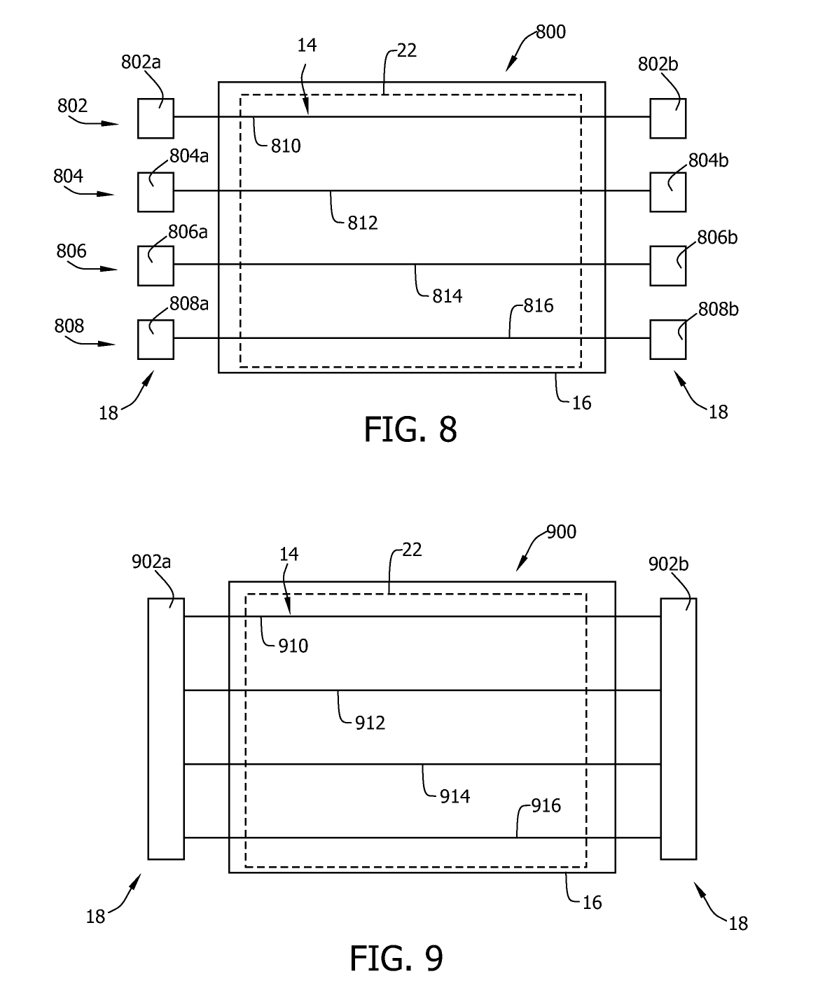

FIGS. 8 and 9 show exemplary embodiments, which may be combined with other embodiments herein, in which a coating apparatus (e.g., coating apparatus 800 or coating apparatus 900) are configured for implementing a plurality of wires 14, each of the wires being for heating coating material to be deposited on substrate 12.

According to the exemplary embodiment of FIG. 8, coating apparatus 800 includes an actuator system 18 configured to tension each of wires 810, 812, 814, 816 individually. Thereby, at least a portion of the plurality of wires may be appropriately tensioned within a reactor 22. In particular, actuator system 18 may include a plurality of actuator sub-systems, each of the sub-systems being adapted for tensioning at least a portion of an associated wire.

For example, in the exemplary embodiment, actuator system 18 includes a first actuating sub-system 802 adapted for tensioning, at least partially, a wire 810. First actuating sub-system 802 may operate in an analogous manner as the actuator systems in embodiments previously described. Furthermore, first actuating sub-system 802 may be adapted for feeding a new portion of wire in an analogous manner as previously described. First actuating sub-system 802 may include elements 802a, 802b for effecting wire tensioning and, optionally, wire feeding as previously described. For example, but not limited to, each of elements 802a, 802b may include a wire roller (not shown) operatively coupled to a motorised drive (not shown) in order to actuate wire 810 according to embodiments herein.

Exemplary coating apparatus 800 may further include a second, third, and fourth actuator sub-systems 804, 806, 808 including, respectively, elements 804a and 804b, 806a and 806b, 808a and 808b. Each of these actuator sub-systems may be configured to actuate a respective wire 812, 814, 816. The number of actuator sub-systems and wires in this exemplary embodiment is not limiting.

The actuator sub-systems may be coupled to a common control system for allowing automatic or manual control thereof. Alternatively, each of the actuator sub-systems may be coupled to an individual control system for allowing individual control of each sub-system, either automatically or manually.

According to the exemplary embodiment of FIG. 9, coating apparatus 900 includes an actuator system 18 configured to tension wires 910, 912, 914, 916 in a simultaneous manner. For example, actuator system 18 may include elements 902a, 902b for effecting wire tensioning and, optionally, wire feeding of the plurality of wires in an analogous manner as for other embodiments herein. For example, but not limited to, each of elements 802a, 802b may include a wire roller, each of the rollers being configured to store a batch of each of the plurality of wires. Furthermore, each of elements 902a, 902b may further include a motorised drive (not shown) operatively coupled to wire rollers for actuating the plurality of wires according to embodiments herein.

A coating apparatus according to embodiments herein may be adapted for actuating any number of wires appropriate for a particular application thereof. For example, coating apparatus 800 may be adapted for actuating at least 20 wires or, more specifically, at least 30 wires or, more specifically, at least 40. Embodiments herein referring to “a wire” generally include one or a plurality of wires.

A coating apparatus according to embodiments herein may further include a control system adapted for controlling a coating system such that a coated substrate can be manufactured according to the present disclosure. For example, such a control system may be adapted for performing the method steps described above regarding FIGS. 2 and 4.

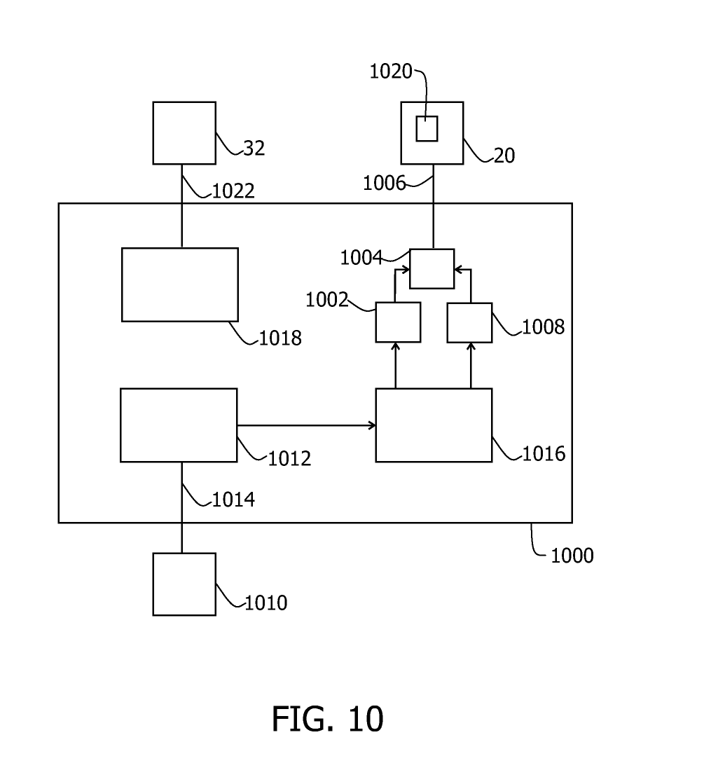

FIG. 10 shows a schematic diagram of a control system 1000 adapted for operating a coating apparatus according to embodiments herein. In particular, control system 1000 may be adapted to control actuator system 18 for tensioning the wire during the coating. In particular, control system 1000 may include a tension control system 1002 configured to control a torque generated by the motorised drive and coupled to the wire 14, so that tension of wire 14 is adjustable during operation of a coating apparatus.

Control system 1000 may further include a motor control system 1004 configured to operate motorised drive 20 through a connection 1006. As set forth above, motorised drive 20 may include at least one motorised sub-drive 20a, 20b, 20c, 20d for operation of different elements of actuator system 18. In particular, motorised drive 20 may include at least one electrical motor 1020. Motor control system 1004 may be configured to individually operate a plurality of sub-drives of motorised drive 20. In particular, motor control system 1004 may include a control sub-system (not shown) for controlling each of the sub-drives of motorised drive 20. Alternatively, motor control system 1004 may be configured to simultaneously operate a plurality of sub-drives of motorised drive 20. Tension control system 1002 may be operatively coupled to motor control system 1004 in order to adjust tension of wire 14.

In particular, tension control system 1002 may be configured to control a torque generated by motorised drive 20 and coupled to the wire 14, so that tension of the wire 14 is adjustable during operation of the coating apparatus. For example, tension control system 1002 may be configured for controlling motorised drive 20 (e.g., through motor control system 1004) for generating a pre-determined torque by the motor or motors of motorised drive 20. A torque control of at least one motor in motorised drive 20 typically facilitates guarantying that a pre-determined tension is applied onto wire 14 without generation of excessive stress on wire 14. Thereby, it is generally facilitated to extend the operational lifetime of wire 14.

According to one embodiment, which might be combined with other embodiments herein, motorised drive 20 includes at least one electrical motor. According to some embodiments, the at least one electrical motor is a servomotor. For example, in the exemplary embodiment of FIG. 1, motorised drive 20 may include one electrical motor for operating pull device 24a. This electrical motor may be a servomotor controlled by motor control system 1004 using torque control. Alternatively, the at least one electrical motor is a stepper motor. For example, motorised drive 20 of coating apparatus 10 may include a stepper motor.

In case motorised drive 20 includes one or more servomotors, motor control system 1004 may include a motion control device configured to operate servomotors. In case motorised drive 20 includes one or more stepper motors, motor control system 1004 may include a motion control device configured to operate stepper motors (e.g., one or more stepper power supplies).

A motorised drive 20 including at least one servomotor may facilitate maintaining a pre-determined wire tension with a better accuracy. For example a motorised drive including at least one servomotor may be configured to adjust tension of wire 14 with a tension accuracy of at least 15% or, more specifically, 10% or, even more specifically, 5%. Alternatively, motorised drive 20 (in particular if drive 20 includes at least one stepper motor) may be configured to adjust tension of wire 14 with a tension accuracy of at least 60% or, more specifically, 50% or, even more specifically, 40%. A motorised drive 20 including at least one servomotor facilitates minimizing tension ripple. For example a motorised drive including at least one servomotor may be configured to adjust tension of wire 14 with a tension ripple of at least 4% or, more specifically, 2%, or, even more specifically, 1%.

A motorised drive 20 including at least one stepper motor may facilitate at least one of: (i) reducing system costs; (ii) enhancing system operability; and/or (iii) reducing space required for implementation of motorised drive 20 in a coating apparatus according to embodiments herein.

According to one embodiment, which might be combined with other embodiments herein, motorised drive 20 includes two motorised sub-drives 20a, 20b, as shown in exemplary coating apparatus 300 of FIG. 3. Each of motorised sub-drives 20a, 20b may include at least one electrical motor. For example, each of motorised sub-drives 20a, 20b may include one servomotor controlled by motor control system 1004 using torque control. Thereby, tension of wire 14 may be maintained with high accuracy. Alternatively, at least one of motorised sub-drives 20a, 20b may include one stepper motor.

According to another embodiment, which might be combined with other embodiments herein, motorised drive 20 includes four motorised sub-drives 20a, 20b, 20c, and 20d as in exemplary coating apparatus 700 of FIG. 7. Each of motorised sub-drives 20a, 20b, 20c, 20d may include at least one electrical motor. In one embodiment: (i) each of motorised sub-drives 20a, 20b of coating apparatus 700 includes one servomotor controlled by motor control system 1004 using torque control; and (ii) each of motorised sub-drives 20c, 20d includes one servomotor, at least one of the servomotors of motorised sub-drives 20c, 20d being controlled, optionally, by motor control system 1004 using speed control. The speed control may be implemented by, e.g., using a zero speed set-point, a torque which is two or three times the torque generated by the sub-drives adjusting tension of wire 14, and using position control for wire transport. The other motorised sub-drive 20c, 20d may be controlled by using torque control. Thereby, tension of wire 14 may be maintained with high accuracy.

Alternatively, in coating apparatus 700: (i) each of motorised sub-drives 20a, 20b of coating apparatus 700 may include one stepper motor controlled by motor control system 1004 using slow pulses; and (ii) each of motorised sub-drives 20c, 20d may include one stepper motor, at least one of the stepper motors of motorised sub-drives 20c, 20d being controlled by motor control system 1004 using slow pulses. The other motorised sub-drive 20c, 20d may be controlled without pulses, but using, for example, a zero speed set-point, optionally a torque which is two or three times the torque generated by the sub-drives adjusting tension of wire 14, and, optionally, using position control for wire transport. Thereby, tension of wire 14 may be maintained with high accuracy.

According to embodiments herein a stepper motor of motorised drive 20 may be controlled using slow pulses. According to embodiments herein, a slow pulse may cause a rotation between 0.125 degrees and 1.8 degrees per pulse, such as 0.225 degrees or less per pulse.

According to embodiments herein, actuator system 18 may be configured (in particular in association with tension control system 1002) for maintaining tension of wire 14 during the coating at a pre-determined tension value. Such a pre-determined value may be a tension value ranging from about 0.5 N to 1.5 N, such as 1 N. The pre-determined value may be any tension value that allows a coating apparatus according to embodiments herein to prepare a coating material for being appropriately deposited over a substrate. Typically, the tension values is predetermined taking into account the mechanical properties of the wire, so that generation of excessive stresses thereon are avoided.

According to embodiments herein, control system 1000 may further include a wire feed control system 1008 operatively coupled to a wire feeding device (such as the wire feeding devices described above) for feeding a new portion of wire, so that a coating material 28 can be heated with the new wire portion as detailed above. Typically, wire feed control system 1008 is operatively coupled to motor control system 1002 in order to feed the new wire portion by operation of motorised drive 20. In particular, wire feed control system 1008 may be configured for: (i) automatically supplying (i.e. feeding) a new wire portion during coating; and/or (ii) automatically supplying a new wire portion at predetermined time intervals, as detailed above.

A coating apparatus according to embodiments herein may include a sensor system 1010 configured for measuring at least one parameter of wire 14 such as, but not limited to, tension, mechanical stress, elasticity, wire temperature, or any other parameter of wire 14. In particular, sensor system 1010 may include a tension transducer implemented in actuator system 18 for measuring tension of wire 14. In particular, the tension transducer may be implemented in an element of actuator system 18 applying a torque onto wire 14 such as, but not limited to, pull device 24a, wire roller 324a and/or wire roller 324b.

The coating apparatus may be configured for operating motorised drive 20 according to the measured at least one wire parameter. For example, but not limited to, tension control system 1002 may be further configured to control a torque (or torques) generated by motorised drive 20 using a closed-loop control for maintaining wire tension at a substantially constant pre-determined value. The control variable for the closed-loop control may be, for example, a measured wire tension. Other measured parameters of wire 14 may be used for adjusting tension of wire 14 such as mechanical stress, elasticity, wire temperature, or any other suitable parameter of wire 14.

According to one embodiment, which may be combined with any of the embodiments discussed herein, a new portion of wire 14 may be fed according to embodiments herein when one measured property of wire 14 reaches a predetermined value or a predetermined value range. Therefor, a parameter indicating an excessive wear of wire 14 caused by a continuous heating and/or interaction with coating material may be used. For example, a coating apparatus according to embodiments herein may be configured for feeding a new wire portion when the wire elasticity exceeds a predetermined value, which predetermined value indicates an excessive wear of a wire portion.

Control system 1000 may include a sensor control system 1012 for implementing a closed-loop control as described above. Sensor control system 1012 may be cooperatively coupled to sensor system 1010 through a connection 1014. Typically Sensor control system 1012 is configured to process information from sensor system 1010 and to enable closed-loop control of the actuation system. For example, sensor control system 1012 may be associated to a regulator 1016 for implementation of closed-loop control of motorised drive 20 through tension control system 1002 and motor control system 1004. Such a closed-loop control may implement any control scheme suitable for allowing a coating apparatus to function as described herein. For example, the closed-loop control may implement control schemes based on logic or sequential controls, feedback or linear controls, or combinations thereof. In particular, such a closed-loop control may implement a PID based control scheme.

According to embodiments herein, control system 1000 may include a heating control system 1018 for controlling heating system 32 according to embodiments herein. Heating control system 1018 may be operatively coupled to heating system 32 through a connection 1022. Heating control system 1018 may be configured to control the current applied to wire 14 in order to perform coating as described herein. According to one embodiment, heating control system 1018 is operatively coupled to sensor control system 1012 in order to control temperature of wire 14 (or at least a portion thereof) by using a wire parameter measured by sensor system 1010. For example, but not limited to, heating control system 1018 may regulate temperature of wire 14 by using a parameter measured by sensor system 1010 such as, but not limited to, the actual value of wire temperature. Sensor system 1010 may include a sensor suitable for measuring wire temperature, such as, but not limited to a dual channel infrared pyrometer.

According to embodiments herein, control system 1000 is a real-time controller. According to embodiments of the present disclosure, such a real-time controller may include any suitable processor-based or microprocessor-based system, for example a computer system, which includes, among others, microcontrol systems, application-specific integrated circuits (ASICs), reduced instruction set circuits (RISC), logic circuits, and/or further thereto, any other circuit or processor that is capable of executing the functions described herein. In certain embodiments, control system 1000 is a microprocessor including read-only memory (ROM) and/or random access memory (RAM), such as, e.g., a 32-bit microcomputer with a 2-Mbit ROM, and a 64 Kbit RAM. The term “real-time” refers to outcomes taking place a substantially short period of time after a change in the inputs affect the outcome, with the time period being a design parameter that may be selected based on the importance of the outcome and/or the capability of the system processing the inputs to generate the outcome.

According to embodiments herein, wire 14 may be a non-rigid wire. According to embodiments herein, the term “non-rigid” refers to a wire which is not self-supporting. Wire 14 may be a flexible wire. Wire 14, according to embodiments herein may include, or consist of, Ta, W, or any other material suitable for allowing the wire to function as described herein, such as, but not limited to carbon. According to some embodiment, wire 14 may have a thickness ranging from about 0.1 mm to about 0.6 mm or, more specifically, from about 0.2 mm to about 0.5 mm or, even more specifically, from about 0.3 mm to about 0.4 mm. Alternatively, wire 14 may have any suitable thickness such as, but not limited to, a thickness between 0.2 to 2 mm.

A wire according to embodiments herein may, for example, but not limited to, include a cylindrical or planar cross-section. Generally, a wire according to embodiments herein may have any cross-section suitable for allowing a coating apparatus to be operated as described herein.

A coating apparatus according to embodiments herein may be a hot wire chemical vapour coating (HWCVD) apparatus. In particular, the coating apparatus may be configured such that coating material 28 undergoes a chemical reaction by interaction thereof with a wire portion in the hot area of the coating apparatus (e.g., reactor 22). For example, the coating apparatus may be configured for introduced coating material 28 as a volatile precursor in reactor 22 (or any other kind of hot area in the coating apparatus). The coating apparatus may be configured for inducing reaction of the volatile precursor by interaction with a heated wire portion (such as wire portion 14a). The coating apparatus may be further configured for removing by-products of the process by, for example, implementing a gas flow through reactor 22.

A HWCVD according to embodiments herein may be configured to deposit materials over substrate 12 in a predetermined form, such as, but not limited to, monocrystalline, polycrystalline, amorphous, epitaxial form, and combinations thereof. A HWCVD according to embodiments herein may be configured to deposit different types of materials (or a combination thereof), such as, but not limited to, silicon, carbon fiber, carbon nanofibers, carbon nanotubes, silicon oxide (such as, but not limited to, SiO₂), silicon-germanium, silicon carbide, silicon nitride, silicon oxynitride, titanium nitride, a high-k dielectric, amorphous Si, microcrystalline Si, p-doped Si and/or n-doped Si.

According to embodiments herein, substrate 12 may be a rigid or a flexible substrate for manufacturing an electronic device. For example, but not limited to, substrate 12 may be a substrate for manufacturing a touch panel, a DRAM or a flash memory. In particular, a coating apparatus according to embodiments herein may be configured to fabricate, at least partially, a touch panel, a DRAM or a flash memory. Embodiments herein contemplate a modular manufacturing system including a coating apparatus as described herein for manufacturing one of these devices. Embodiments herein also contemplate a method for manufacturing one of these devices implementing at least one of the methods described above. For example, a coating apparatus according to embodiments herein may be adapted for manufacturing a layer of amorphous Si, microcrystalline Si, p-doped Si and n-doped Si, silicon nitride, silicon oxynitride for one of the above devices. The present disclosure also contemplates methods of manufacturing these layers.

Exemplary embodiments of systems and methods for manufacturing a substrate are described above in detail. The systems and methods are not limited to the specific embodiments described herein, but rather, components of the systems and/or steps of the methods may be utilized independently and separately from other components and/or steps described herein.

For example, a coating apparatus according to embodiments herein may be configured to couple a torque generated by the motorised drive to wire 14 through a non-resilient coupling system, such as the coupling systems described above (e.g., pull device 24a or wire rollers 324a, 324b). In particular, actuator system 18 may actuate wire 14 without the intermediation of a spring coupling system for tensioning of wire 14. It should be noted that such a non-resilient coupling system according to embodiments herein facilitates an easier tensioning of wire 14 as compared to a spring coupling system for tensioning of wire 14. Such a spring coupling system usually requires a pretension procedure that may be complex and/or inaccurate.

As another example, the present disclosure also contemplates a coating apparatus including: (i) a vacuum chamber for coating a substrate; (ii) a reactor adapted to receive at least a wire portion for heating material to be deposited on the substrate; (iii) a motorised drive, including at least one electrical motor; and (iv) a wire roller system (e.g., a system including wire rollers 324a, 324b described herein) configured for feeding and positioning at least the wire portion in the reactor. In this embodiment, the motorised drive is operatively coupled to the wire roller system, so that, in use, at least the wire portion positioned in the reactor can be tensioned in an adjustable manner by the motorised drive.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. While various specific embodiments have been disclosed in the foregoing, those skilled in the art will recognize that the spirit and scope of the claims allows for equally effective modifications. Especially, mutually non-exclusive features of the embodiments described above may be combined with each other. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A coating apparatus comprising:
a vacuum chamber for coating a substrate;
a reactor adapted to receive at least a wire portion for heating material to be deposited on said substrate;
a motorised drive, including at least one electrical motor; and
a wire roller system configured for feeding and positioning at least said wire portion in said reactor,
wherein said motorised drive is operatively coupled to said wire roller system, so that, in use, at least said wire portion positioned in said reactor can be tensioned in an adjustable manner by said motorised drive.

2. The coating apparatus according to claim 1, wherein said coating apparatus is a hot wire chemical vapour coating apparatus.

3. A coating apparatus comprising:
a vacuum chamber for coating a substrate with coating material heated by a wire; and
an actuator system including a motorised drive, said actuator system being configured for tensioning said wire during the coating.

4. The coating apparatus according to claim 3, wherein said actuator system is configured for tensioning said wire by coupling a torque generated by said motorised drive to said wire.

5. The coating apparatus according to claim 3, wherein said motorised drive includes at least one electrical motor selected from the group consisting of servomotors and stepper motors.

6. The coating apparatus according to claim 3, further comprising a tension control system configured to control a torque generated by said motorised drive and coupled to said wire for tensioning thereof, so that tension of said wire is adjustable during operation of said coating apparatus.

7. The coating apparatus according to claim 3, wherein the actuator system is configured for feeding a new portion of wire into a reactor of said coating apparatus, so that a coating material in said reactor can be heated with said new wire portion before deposition of the coating material on the substrate.

8. The coating apparatus according to claim 7, further comprising a feed control system operatively coupled to said actuator system and configured such that, in use:
said new wire portion is automatically supplied during coating; and/or
said new wire portion is automatically supplied at predetermined time intervals.

9. The coating apparatus according to claim 3, further comprising a heater configured to heat at least a wire portion to a temperature of at least 1400° C.

10. The coating apparatus according to claim 3, wherein said coating apparatus is a hot wire chemical vapour coating apparatus.

11. A method of manufacturing a coated substrate, said method comprising:
tensioning a wire by an actuator system including a motorised drive;
coating said substrate with a coating material, the coating being under vacuum conditions,
wherein said coating includes heating at least a portion of said wire to an operating temperature for inducing a temperature increase in said coating material before said coating material is deposited over substrate.

12. The method according to claim 11, further including:
coupling a torque generated by said motorised drive to said wire through a non-resilient coupling system; and
adjusting tension of at least the heated portion of said wire through said torque.

13. The method according to claim 11, further including:
operating said actuator system for feeding a new portion of said wire 14, so that said coating material can be heated with said new wire portion before deposition of the coating material on the substrate.

14. The method according to claim 13, wherein:
said new wire portion is fed while coating material is being deposited over substrate; and/or
said new wire portion is fed at predetermined time intervals.

15. The method according to claim 11, further including heating at least said wire portion to a temperature of at least 1400° C.

16. The coating apparatus according to claim 6, wherein the tension of said wire is adjustable during operation of said coating apparatus with a tension accuracy of at least 15% or with a tension ripple of at least 4%.

17. The coating apparatus according to claim 6, further comprising a sensor system configured for measuring at least one parameter of the wire, wherein the tension control system is configured to control the torque generated by the motorised drive according to the measured at least one parameter of the wire.

18. The coating apparatus of claim 9, wherein the actuator system includes a wire feeding system operated by said motorised drive for feeding the new portion of wire into the reactor of said coating apparatus.

19. The coating apparatus of claim 18, wherein the wire feeding system is a wire roller system.

20. The method according to claim 11, wherein the tension is adjusted with a tension accuracy of at least 15% or with a tension ripple of at least 4%.
